(19) United States
(12) Patent Application Publication
(10) Pub. No.: US 2014/0167785 A1
(43) Pub. Date: Jun. 19, 2014

(54) Method and apparatus to detect and measure current and transfer charge

(71) Applicant: Josef C. Shaw, Boston, VA (US)

(72) Inventor: Josef C. Shaw, Boston, VA (US)

(21) Appl. No.: 13/694,602

(22) Filed: Dec. 17, 2012

(51) Int. Cl. G01R 19/00; H01F 27/40

(52) U.S. Cl. CPC G01R 19/0092; H01F 27/402
USPC 324/654; 336/105

(57) ABSTRACT

A passive electrical circuit element is disclosed that comprises an inductor surrounded by an electrically conductive sheet, wherein the electrically conductive sheet is electrically insulated from the inductor, and wherein the electrically conductive sheet is configured to transfer charge from the inductor to the conductive sheet in proportion to the current in the inductor.

A transducer used to measure an unknown current in a circuit is disclosed that includes an inductor. The transducer comprises an electrically conductive sheet adapted to surround the inductor, while being electrically insulated from the inductor, and further including a device used to measure the charge transferred to the electrically conductive sheet when an unknown current is applied to the inductor.

### CROSS REFERENCE TO RELATED APPLICATIONS

None

### STATEMENT REGARDING FEDERALLY SPONSORED RESEARCH OR DEVELOPMENT

No federally sponsored research or development is disclosed or claimed herein.

### THE NAMES OF PARTIES TO A JOINT RESEARCH AGREEMENT

This application is not the subject of any joint research agreement.

### INCORPORATION-BY-REFERENCE OF MATERIAL SUBMITTED ON A COMPACT DISK

Not Applicable

### BACKGROUND OF THE INVENTION

An inductor (also choke, coil or reactor) is a passive two-terminal electrical component that stores energy, according to classical theory, in its magnetic field. For comparison, a capacitor stores energy in an electric field, and a resistor does not store energy but rather dissipates energy as heat.

Any conductor demonstrates some inductance anytime an electric current flows through the conductor. An inductor is typically made of a wire or other conductor wound into a coil, to increase the magnetic field. According to the classical theory, when the current flowing through an inductor changes, creating a time-varying magnetic field inside the coil, a voltage is induced, according to Faraday's law of electromagnetic induction, which by Lenz's law opposes the change in current that created it. Inductors are one of the basic components used in electronics where current and voltage change with time, due to the ability of inductors to delay and reshape alternating currents.

An inductor is usually constructed as a coil of conducting material, typically copper wire, wrapped around a core either of air or of ferromagnetic material. Core materials with a higher permeability than that of air increase the magnetic field and confine it closely to the inductor, thereby increasing the inductance. Low frequency inductors are constructed like transformers, with cores of electrical steel laminated to prevent eddy currents. ‘Soft’ ferrites are widely used for cores above audio frequencies, since they do not cause the large energy losses at high frequencies that ordinary iron alloys do. Inductors come in many shapes. Most are constructed as enamel coated wire (magnet wire) wrapped around a ferrite bobbin with wire exposed on the outside, while some enclose the wire completely in ferrite and are referred to as “shielded”. Some inductors have an adjustable core, which enables changing of the inductance. Inductors used to block very high frequencies are sometimes made by stringing a ferrite cylinder or bead on a wire.

Small inductors can be etched directly onto a printed circuit board by laying out the trace in a spiral pattern. Some such planar inductors use a planar core. Small value inductors can also be built on integrated circuits using the same processes that are used to make transistors. Aluminum interconnect is typically used, laid out in a spiral coil pattern. However, the small dimensions limit the inductance, and it is far more common to use a circuit called a “gyrator” that uses a capacitor and active components to behave similarly to an inductor.

### BRIEF SUMMARY OF THE INVENTION

As defined herein, a “capductor” is a passive electronic device that can be used to create potential in one part of an electronic circuit that is proportional to the current in another part of a circuit without influencing the other part. Capductors could be used as transceivers in a variety of detection devices or in the direct measurement of pulsed or sinusoidal currents, such as in feedback circuits. At present, transceivers generally require the use of operational amplifiers, which are limited in functionality in so far as amplitude and frequency are concerned and often produce an output different in phase from the input. The present invention solves this problem by providing a device to measure pulsed or sinusoidal currents.

### BRIEF DESCRIPTION OF THE SEVERAL FIGURES OF THE DRAWINGS

FIG. 1 depicts a curved conductor, and the various forces that act on current as it travels through the conductor.

FIG. 2 shows an electrical circuit used to detect and measure current and transfer charge according to the invention.

FIG. 3 shows the behavior of a magnetic flux inside of a coil.

FIG. 4 shows a photo of square wave and the output inductive voltages VL and capacitive voltages VC measured using the circuit of FIG. 2.

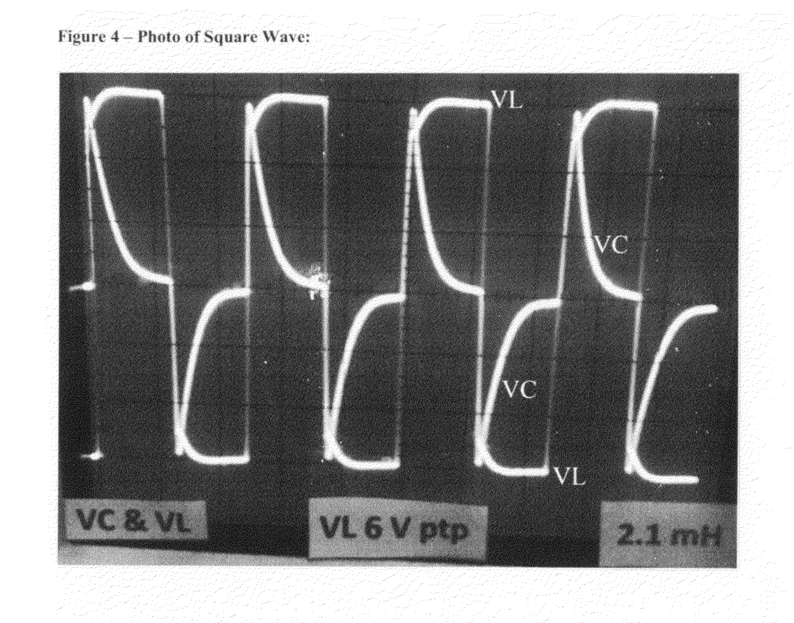

FIG. 5 shows a photo of sinusoidal wave and the output inductive voltages VL and capacitive voltages VC measured using the circuit of FIG. 2.

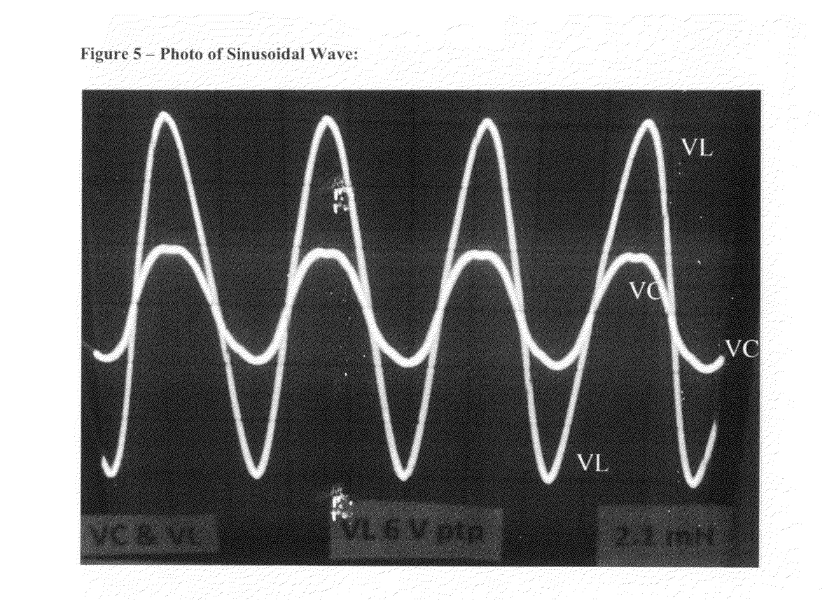

FIG. 6 shows an electrical circuit used to detect and measure current and transfer charge according to the present invention, with direct and indirect placement of capductors in the circuit of interest.

FIG. 7 shows maximum charge with 50 KHz Square Wave and 500 K-Ohm Load for a single row of windings at currents according to the invention.

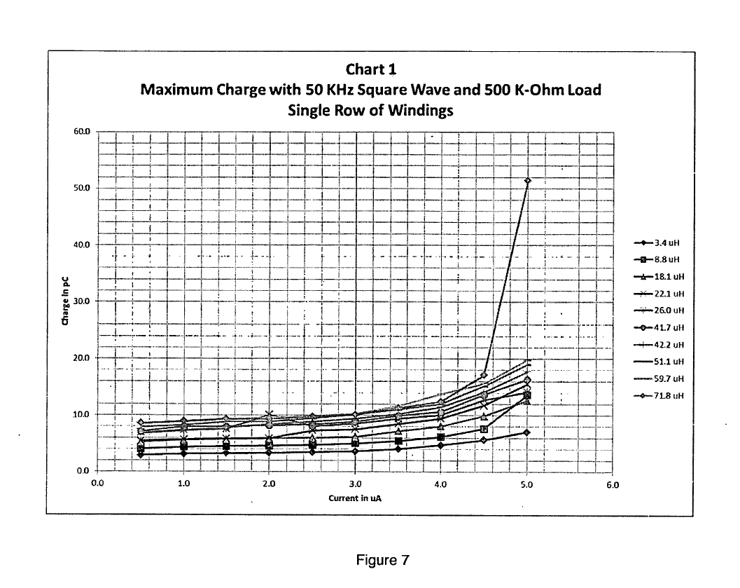

FIG. 8 shows maximum charge with 50 KHz Square Wave and 50 K-Ohm Load for a single row of windings according to the invention.

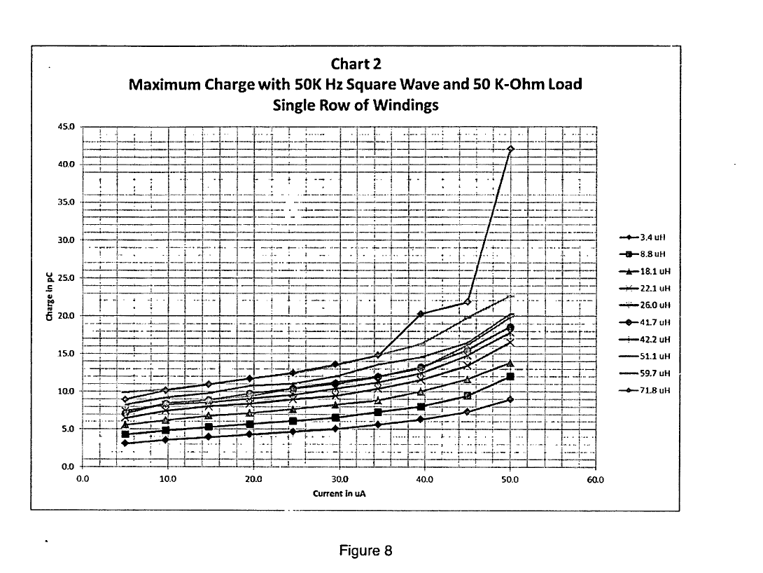

FIG. 9 shows maximum charge with 50 KHz Square Wave and 5 K-Ohm Load for a single row of windings at currents according to the invention.

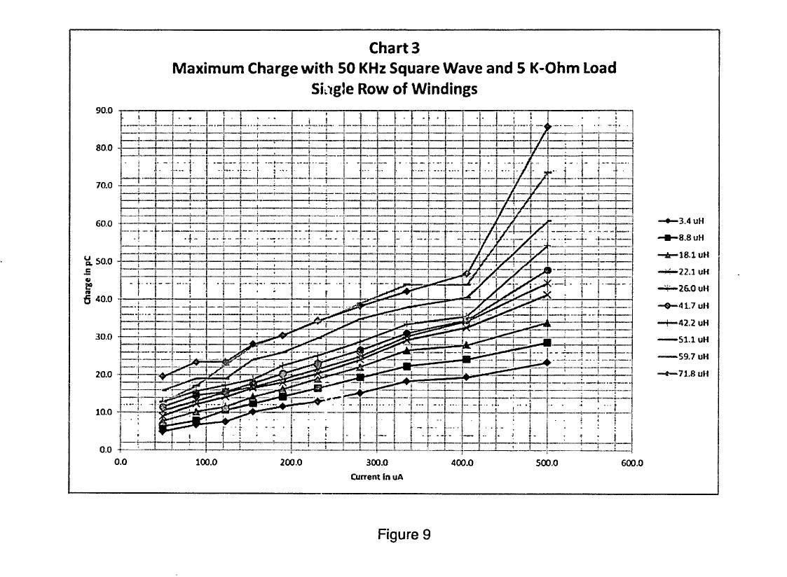

FIG. 10 shows maximum charge with 50 KHz Square Wave and 500 K-Ohm Load for a single row of windings at another set of currents according to the invention.

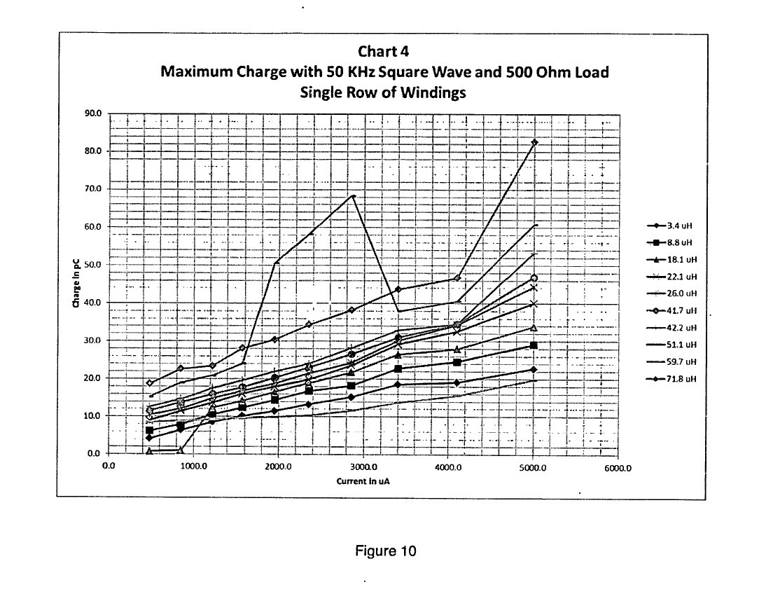

FIG. 11 shows maximum charge with 50 KHz Square Wave and 5 K-Ohm Load for a single row of windings at another set of currents according to the invention.

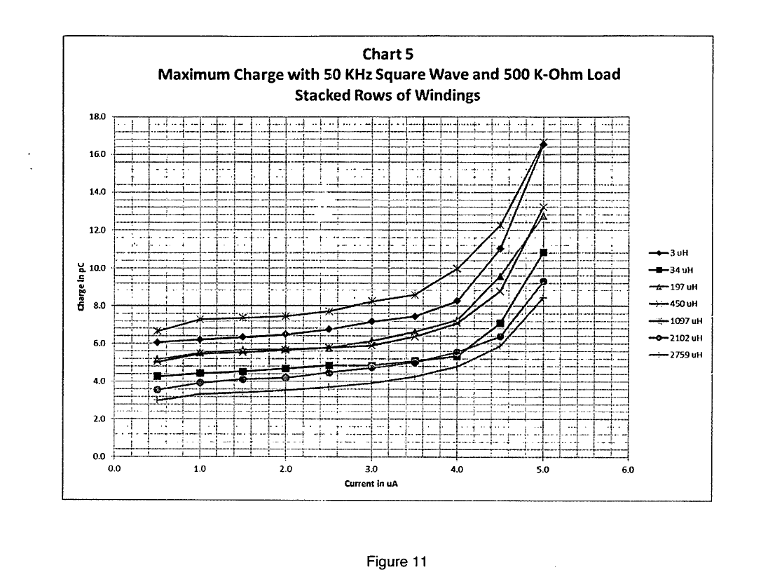

### DETAILED DESCRIPTION OF THE INVENTION

Two passive electronic components widely used for energy storage and signal filtering are capacitors and inductors. Capacitors consist of two parallel conducting surfaces separated by non-conducting dielectric materials. Inductors consist of one or more coils of conducting wires wound around ferrous or air cores. Capacitors store energy through the separation of charge and pass fluctuating current, while impeding constant current. Inductors have been thought to store energy in the magnetic fields that they create. Inductors pass constant current, while impeding fluctuating current. A detailed explanation about capacitors and inductors, as well as electronics in general, can be found in The Art of Electronics by Paul Horowitz and Winfield Hil, Cambridge University Press, 1989, Cambridge, U.K.

Although the instant invention is not dependent on any particular electromagnetic theory, it is hypothesized that magnetic forces present in the interior of a coil tend to push current-carrying electrons toward the outside of the coil, creating a region of positive charge at the inside of the coil. In other words, some portion of the electrical energy is stored in a coil in exactly the same manner as in a capacitor, as a result of separated charge, rather than all the energy stored in the magnetic field of the coil, as currently accepted by traditional electromagnetic theory. In fact, it is theorized that some electrons are actually ejected from the outside of the coil, causing a net positive charge in the inside of the coil. Another way of visualizing the phenomena is that electrons are forced towards the outside of the coil by centripetal forces. Because the path followed by the electrons is shorter on the inner turns than on the outer turns, the electrons must travel faster around the outer turns. This velocity differential between the outer turns and inner turns causes a charge drift towards the outer turns, and an accompanying negative electric field. The charge drift is very sensitive, and enables extremely fine measurements of charge and thus current in an inductive element.

A capductor is a passive electrical circuit element that comprises an inductor surrounded by an electrically conductive sheet, wherein the electrically conductive sheet is electrically insulated from the inductor, and wherein the electrically conductive sheet is configured to transfer charge from the inductor to the conductive sheet in proportion to the current in the inductor. The electrically conductive sheet can have a time constant that is about equal to the time constant of the inductor, thereby forming a capacitive surface with a voltage in phase with the inductive coil when alternating current is applied to the inductive coil. Alternately, the time constant for both the inductor and the electrically conductive sheet can be less than one fifth of the rise time of the current in the inductor. In another embodiment, the time constant of both the inductor and the electrically conductive sheet are less than one tenth the period of the current in the inductor.

An unknown current in a circuit that includes an inductor is can be measured using a capductor. The method comprises surrounding the inductor with an electrically conductive sheet wherein the electrically conductive sheet is electrically insulated from the inductor, wherein the electrically conductive sheet is configured to transfer charge from the inductor to the conductive sheet in proportion to the current in the inductor. The charge transferred to the conductive sheet in response to the unknown current is measured and correlated to the charge transferred to the unknown current in the circuit.

A transducer used to measure an unknown current in a circuit can that includes an inductor can be constructed. The transducer comprises an electrically conductive sheet adapted to surround the inductor, while being electrically insulated from the inductor, and further including a device used to measure the charge transferred to the electrically conductive sheet when an unknown current is applied to the inductor.

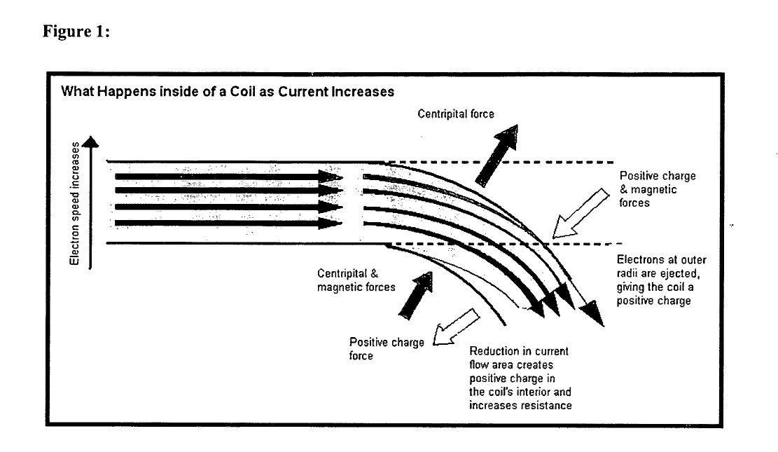

FIG. 1 shows the velocity gradient within the conductor in detail. As depicted in FIG. 1, electron velocity within the coil increases toward the outer radii of the coil, giving the coil a positive charge towards the inner radii of the coil. Centripetal and magnetic forces push the electrons outwardly. The differences are of course very small, enabling extreme sensitivity because measurements using a capductor are based on the small differences in electric field of the capductor.

Using this theory a transducer to detect and measure charge in an inductor a conductive surface or foil is placed to surround the inductance coil of unknown current. The combination of the inductance coil and the conductive foil form a capductor according to the invention. In this manner, the inductor is somewhat like a capacitor in configuration; that is the electrically insulated coil is one surface and the conductive surface or foil the other surface. When current is applied to the coil, the electrically conductive surface or foil develops a negative charge on its surface, proportional to the inductors positive charge. Charge is thus transferred in proportion to the current in the inductor.

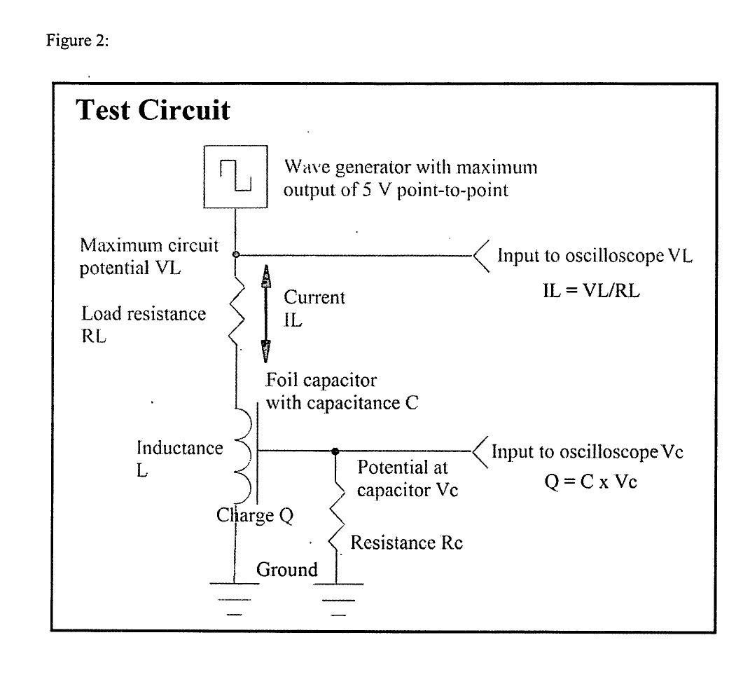

Referring to FIG. 2, it is possible to determine the magnitude of the charge that various magnitudes of current produce in inductors. This is accomplished by wrapping the inductors with conducting copper film that was insulated from the conducting wires that make up the inductors, and measuring the potential in the foil that the current through the inductors caused. The resulting passive electronic component is a hybrid of a capacitor and an inductor, hereafter referred to as a capductor. FIG. 2 shows the circuit used to measure current utilizing a capductor. In the test circuit of FIG. 2, a wave generator generates a signal which passes through the capductor. A load resistance is interposed between the signal generator and the capductor. Current IL is measured at the maximum circuit potential VL, at a point between the wave generator and the load resistance, with an oscilloscope. A second resistance is interposed between the capductor foil element and the circuit ground. A second oscilloscope measures the potential of the foil element of the capductor as shown. Because of the sensitivity of the potential at the capacitor, it is possible to achieve extremely accurately the current through the inductive element of the capductor. Of course, the foil element of the capductor could be used on any inductance in any circuit to make inductance measurements.

By appropriately sizing the inductance and capacitive value of a capductor to the resistive load and signal frequency in the circuit in which the capductor is to be used, passive transceivers can be constructed to handle any combination of amplitude and frequency. Moreover, the time constants of inductive and capacitive elements of a capductor can be adjusted in such a manner that the output current and potential are in phase with the input current and potential.

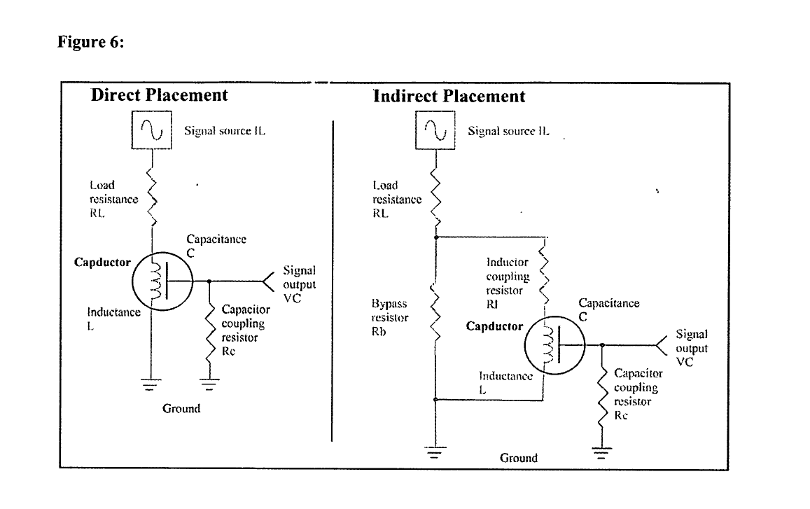

Capductors can be employed in two modes, direct and indirect, depending on the loading requirements and maximum current magnitude of the circuit in which they are used. In the direct mode, the resistive load of the circuit is coupled directly with the capductor. This generally would be the scenario used in circuits with relatively low maximum levels of currents—less than tenths of an ampere—in which the inductive value of the capductor can be appropriately sized to the circuit's resistive load and signal frequency. With higher current levels or circuits in which the inductor cannot be appropriately sized to the circuit's resistive load, a bi-pass resistor of a low level of resistance would be required to limit the amount of current actually passing the inductor and to allow a separate coupling resistor to be placed in series with the inductive portion of the capductor. Both modes are illustrated in FIG. 6. A buffer or unity operational amplifier generally would be used to couple the output of the capductor to another application in order to mitigate signal attenuation.

The achievement of optimum performance in a capductor in some applications requires designing the inductive and capacitive elements of the capductor in such a manner that they have the same time constant. However, there may be applications that require the time constants to be determined in an alternate manner. In pulsed applications, the time constant of both elements should be less than one fifth of the rise time of the pulse. In sinusoidal applications, the time constant of both elements should be less than one tenth the period of the signal. Time constants having larger values than specified above in relation to signal rise time or frequency might produce ringing in the capductor that could adversely affect both the input and output circuits.

Referring to FIG. 6, the time constant Tci of the inductive element of the capductor is:

Tci=L/RL or L/R1

Referring to FIG. 6, the time constant Tcc of the capacitive element of the capductor is:

Tcc=Rc×C

It is possible to determine the magnitude of the charge that various magnitudes of current produce in inductors. The applicant accomplished this by wrapping the inductors with conducting copper film that was insulated from the conducting wires that make up the inductors and measuring the potential in the foil that the current through the inductors caused. The resulting passive electronic component is a hybrid of a capacitor and an inductor, which the applicant calls a capductor.

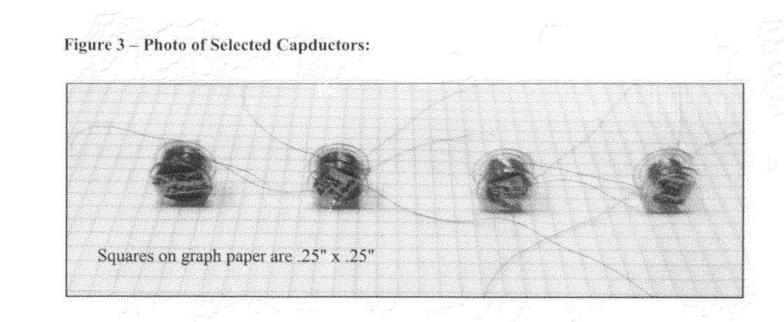

Referring to FIG. 3, photos of representative capductors according to the invention are shown. Two sets of tests are summarized below, utilizing the capductors of FIG. 3, that illustrate the properties of capductors. In the first set of tests, the applicant increased the number of windings of the inductor and the area of the surrounding foil in constant increments or sets of 48 windings, using coils with only a single row of windings on each bobbin, all of the same size. Bobbins were placed end-to-end. AWG 34 digital multi-meter (DMM). In the second set of tests, the applicant stacked rows of 48 windings each in various quantities up to 15 rows on single bobbins of the same size. Inductance again directly was measured using a DMM, but net capacitance was calculated by measuring the time rate of decay of the potential on the foil through a resistance of a known value. Given that each row of windings in the stacked configuration has its own capacitance with respect to the foil, it was not possible to use a DMM to measure capacitance. The equation below was used to perform this calculation. In the equation below, C is capacitance, Rc is the resistance of the resistor connected to the metal foil, and T is the time in which the potential of the foil decayed to half of its initial value.

C=−TRc(ln(0.5))

FIG. 2 shows the circuit used to conduct both sets of tests. Table 1 shows the specifications of the capductors used in the first set of tests, while Table 2 shows the specifications of the capductors used in the second set of tests. These tests were conducted at a frequency of 50 kilo-hertz (KHz), a frequency that was chosen to optimize the performance of both the inductive and capacitive elements in the capductors in order to facilitate analysis of the behavior of the capductors. Charts 1-4 summarize the first set of tests, while Charts 5-8 summarize the second set of tests. FIG. 3 is a photo that illustrates some of the capductors used in the tests. In the charts, uA means micro-amperes, V means volts, mV means milli-volts, uH means micro-henrys, pF means pico-farads, pC means pico-colombs, and K-ohms means kilo-ohms.

TABLE 1
Single Layer of Windings:

| Sets of | Inductance | Capacitance | Resistance at which |
|---|---|---|---|
| Windings | in uH | in pF | Rc was set in K-ohm |
| 1 | 3.360 | 22.47 | 88.3 |
| 2 | 8.775 | 36.41 | 54.8 |
| 3 | 18.11 | 58.86 | 33.4 |
| 4 | 22.06 | 94.25 | 21.0 |
| 5 | 26.00 | 134.4 | 14.5 |
| 6 | 41.70 | 177.0 | 11.1 |
| 7 | 42.20 | 208.8 | 9.37 |
| 8 | 51.11 | 253.2 | 8.86 |
| 9 | 59.71 | 283.0 | 9.06 |
| 10 | 71.76 | 311.6 | 7.42 |

Both sets of tests were conducted with four different resistive loads RL: 500 K-ohms, 50 K-ohms, 5-K-ohms, and 500 ohms in order to test the susceptibility of the inductive element of the capductor to ringing at various loads, given the notorious tendency of inductors to ring at levels of potential in pulsed applications. The time constant of an inductor equals the inductance divided by the resistance of the load. In the first set of tests, Rc was set according to the equation below for all resistive loads RL, in which F is 50 KHz, the frequency at which the tests were conducted, and C is the capacitance between the foil and coil. In the second set of tests, Rc was manually tuned to maximize Vc during each test and varied with values of RL and C.

TABLE 2
Stacked Layers of Windings:

| | | | | | Resistance at | |
|---|---|---|---|---|---|---|
| | | | | | which Rc was | |
| | | | | | set in K-ohm | |
| Sets of | Inductance | | Capacitance | | at indicated | |
| Windings | in uH | | in pF | | value of RL | |
| 500 K-ohms | K-ohms | | 5 K-ohms | | 500 ohms | |
| 2 | 9.991 | 55.1 | 22.5 | 45.5 | 702 | 699 |
| 3 | 33.57 | 33.4 | 26.7 | 153 | 750 | 750 |
| 4 | 196.6 | 49.1 | 20.9 | 75.4 | 758 | 758 |
| 6 | 449.6 | 24.0 | 39.9 | 88.2 | 1020 | 1020 |
| 9 | 1097 | 35.0 | 31.4 | 65.9 | 951 | 951 |
| 12 | 2102 | 36.5 | 35.6 | 135 | 1120 | 1120 |
| 15 | 2759 | 21.8 | 63.1 | 125 | 716 | 716 |

1. A passive electrical circuit element comprising an inductor surrounded by an electrically conductive sheet, wherein the electrically conductive sheet is electrically insulated from the inductor, and wherein the electrically conductive sheet is configured to transfer charge from the inductor to the conductive sheet in proportion to the current in the inductor.

2. The passive electrical circuit element of claim 1 wherein the electrically conductive sheet has a time constant that is about equal to the time constant of the inductor, thereby forming a capacitive surface with a voltage in phase with the inductive coil when alternating current is applied to the inductive coil.

3. The passive electrical circuit element of claim 1 wherein the time constant of both the inductor and the electrically conductive sheet are less than one fifth of the rise time of the current in the inductor.

4. The passive circuit element of claim 1 wherein the time constant of both the inductor and the electrically conductive sheet is less than one tenth the period of the current in the inductor.

5. A method of measuring an unknown current in a circuit that includes an inductor, the method comprising surrounding the inductor with an electrically conductive sheet wherein the electrically conductive sheet is electrically insulated from the inductor, and wherein the electrically conductive sheet is configured to transfer charge from the inductor to the conductive sheet in proportion to the current in the inductor, measuring the charge transferred to the conductive sheet in response to the unknown current, and correlating the charge transferred to the unknown current in the circuit.

6. The method of claim 5 wherein the electrically conductive sheet has a time constant that is about equal to the time constant of the inductor, thereby forming a capacitive surface with a voltage in phase with the inductive coil when alternating current is applied to the inductive coil.

7. The passive electrical circuit element of claim 5 wherein the time constant of both the inductor and the electrically conductive sheet are less than one fifth of the rise time of the current in the inductor.

8. The passive circuit element of claim 5 wherein the time constant of both the inductor and the electrically conductive sheet is less than one tenth the period of the current in the inductor.

9. A transducer used to measure an unknown current in a circuit that includes an inductor, the transducer comprising the electrically conductive sheet element of claim 1 adapted to surround the inductor, and further including a device used to measure the charge transferred to the electrically conductive sheet when an unknown current is applied to the inductor.

10. A transducer used to measure an unknown current in a circuit that includes an inductor, the transducer comprising the electrically conductive sheet of claim 2 adapted to surround the inductor, and further including a device used to measure the charge transferred to the electrically conductive sheet when an unknown current is applied to the inductor.

11. A transducer used to measure an unknown current in a circuit that includes an inductor, the transducer comprising the electrically conductive sheet of claim 3 adapted to surround the inductor, and further including a device used to measure the charge transferred to the electrically conductive sheet when an unknown current is applied to the inductor.

12. A transducer used to measure an unknown current in a circuit that includes an inductor, the transducer comprising the electrically conductive sheet of claim 4 adapted to surround the inductor, and further including a device used to measure the charge transferred to the electrically conductive sheet when an unknown current is applied to the inductor.
